(19) United States
(12) Patent Application Publication
(10) Pub. No.: US 2018/0076251 A1
(43) Pub. Date: Mar. 15, 2018

(54) SOLID-STATE IMAGE CAPTURING DEVICE AND ELECTRONIC APPARATUS

(71) Applicant: SEIKO EPSON CORPORATION, Tokyo (JP)

(72) Inventors: Noriyuki NAKAMURA, Sakata-shi (JP); Kazunobu KUWAZAWA, Sakata-shi (JP); Mitsuo SEKISAWA, Sakata-shi (JP)

(73) Assignee: SEIKO EPSON CORPORATION, Tokyo (JP)

(21) Appl. No.: 15/699,602

(22) Filed: Sep. 8, 2017

(30) Foreign Application Priority Data
Sep. 13, 2016 (JP) 2016-178287

(51) Int. Cl. H01L 27/146; H04N 5/361

(52) U.S. Cl. CPC H01L 27/14636; H04N 5/361; H01L 27/14643; H01L 27/14678

(57) ABSTRACT

A solid-state image capturing device includes: a pixel region including a light receiving element, a transfer gate, a floating diffusion region, and a buffer transistor; and an interconnect that is arranged in an N-th interconnect layer (N is an integer of two or more), and electrically connects the floating diffusion region and the buffer transistor.

### BACKGROUND

### 1. Technical Field

The present invention relates to solid-state image capturing devices, electronic apparatuses using the same, and the like.

### 2. Related Art

In the past, it has been mainstream to use CCDs as solid state imaging elements, but in recent years, significant development has been made on CMOS sensors that can be driven at a low voltage and on which peripheral circuits can be mounted. As a result of taking measures in a manufacturing process such as employing a complete transfer technique and a dark current prevention structure and measures against noise in circuit techniques such as CDS (correlated double sampling), CMOS sensors have been improved and grown into devices surpassing that of CCDs in terms of both quality and quantity. Such significant advancement of CMOS sensors has been made possible by a significant improvement in image quality, and an improvement in charge transfer technique is one factor of this improvement.

As a related technique, a solid-state image capturing device in which a plurality of semiconductor elements that can realize complete transfer of signal charges are arranged as pixels and that has a high spatial resolution is disclosed in JP-A-2008-103647 (Paragraphs 0006-0007, FIGS. 2 and 3). The semiconductor element includes a first conductivity type semiconductor region, a second conductivity type light receiving surface buried region that is buried in an upper portion of the semiconductor region and on which light is incident, a second conductivity type charge accumulation region that is buried in an upper portion of the semiconductor region and accumulates signal charges generated by the light receiving surface buried region, a charge read-out region that receives signal charges accumulated in the charge accumulation region, a first potential control means that transfers signal charges from the light receiving surface buried region to the charge accumulation region, and a second potential control means that transfers signal charges from the charge accumulation region to the charge read-out region.

In JP-A-2008-103647 (Paragraphs 0006-0007, FIG. 3), a charge read-out region (floating diffusion region) is electrically connected to a gate electrode of a signal read-out transistor (hereinafter, referred also as buffer transistor) that constitutes a read-out buffer amplifier via a signal interconnect (refer to FIG. 3). When the parasitic capacitance between this signal interconnect and a semiconductor layer or another interconnect such as a power supply interconnect is large, the conversion gain when signal charges are converted to a signal voltage decreases, and the sensitivity of the solid-state image capturing device decreases. Also, in the case where another interconnect to which a voltage, which is noise to the signal voltage, is applied is arranged in the vicinity of the signal interconnect, if the capacitive coupling between the signal interconnect and the other interconnect is large, the change in potential of the other interconnect adversely affects the potential of the signal interconnect.

### SUMMARY

Some aspects of the invention relate to suppressing the reduction in sensitivity of a solid-state image capturing device due to the reduction in conversion gain when signal charges are converted to a signal voltage by reducing the parasitic capacitance between an interconnect that electrically connects a floating diffusion region and a buffer transistor and a semiconductor layer or another interconnect. Also, some aspects of the invention relate to suppressing an adverse effect in that the change in potential of another interconnect adversely affects the potential of the interconnect by reducing the capacitive coupling between the interconnect that electrically connects the floating diffusion region and the buffer transistor and the other interconnect. Furthermore, some aspects of the invention relates to providing an electronic apparatus that uses such a solid-state image capturing device.

A solid-state image capturing device according to a first aspect of the invention includes: a pixel region including a light receiving element, a transfer gate, a floating diffusion region, and a buffer transistor; and an interconnect that is arranged in an N-th interconnect layer (N is an integer of two or more), and electrically connects the floating diffusion region and the buffer transistor.

According to the first aspect of the invention, as a result of arranging the interconnect that electrically connects the floating diffusion region and the buffer transistor in an interconnect layer above the lowest interconnect layer, the distance between the interconnect and the semiconductor layer increases, and therefore the parasitic capacitance between the interconnect and the semiconductor layer is reduced, and the reduction in sensitivity of the solid-state image capturing device due to the reduction in conversion gain when signal charges are converted to a signal voltage can be reduced.

Here, the solid-state image capturing device may further include: contact plugs of a first group that are arranged in openings of interlayer insulating films of first to N-th layers so as to overlap in plan view, and electrically connect the floating diffusion region and the interconnect; and contact plugs of a second group that are arranged in openings of the interlayer insulating films of the first to N-th layers so as to overlap in plan view, and electrically connect the buffer transistor and the interconnect. Accordingly, the electric path between the floating diffusion region and the interconnect can be reduced, and the electric path between the buffer transistor and the interconnect can also be reduced.

In that described above, the interconnect desirably has a width that is smallest in a plurality of interconnects that are arranged in the pixel region. Accordingly, the distance between the interconnect and another interconnect in the vicinity thereof increases, and as a result, the parasitic capacitance between the interconnect and the other interconnect decreases, and the reduction in sensitivity of the solid-state image capturing device due to the reduction in conversion gain when signal charges are converted to a signal voltage can be reduced. Also, the interconnect desirably does not intersect with another interconnect in plan view. Accordingly, the increase in parasitic capacitance between the interconnect and another interconnect due to the interconnect intersecting with the other interconnect can be prevented from occurring.

Furthermore, a distance between the interconnect and another interconnect in a direction parallel to a principal surface of a semiconductor layer in which the pixel region is provided is desirably larger than a distance between the interconnect and the semiconductor layer in a direction vertical to the principal surface of the semiconductor layer. Accordingly, the parasitic capacitance between the interconnect and another interconnect can be sufficiently smaller than the parasitic capacitance between the interconnect and the semiconductor layer. Note that, in the present application, the semiconductor layer refers to a semiconductor substrate, a well formed in the semiconductor substrate, or an epitaxial layer formed on the semiconductor substrate.

A solid-state image capturing device according to a second aspect of the invention, in the solid-state image capturing device according to the first aspect of the invention, further includes a guard interconnect that is arranged between the interconnect and an interconnect (gate interconnect) connected to the transfer gate in plan view. According to the second aspect of the invention, the capacitive coupling between the interconnect and the gate interconnect can be reduced by the guard interconnect, and as a result, the adverse effect in that the change in potential of the gate interconnect adversely affects the potential of the interconnect can be suppressed.

An electronic apparatus according to a third aspect of the invention includes any of the solid-state image capturing devices described above. According to the third aspect of the invention, as a result of using the solid-state image capturing device in which the parasitic capacitance between the interconnect that electrically connects the floating diffusion region and the buffer transistor and the semiconductor layer or another interconnect is reduced, and the reduction in sensitivity due to the reduction in conversion gain when signal charges are converted to a signal voltage is suppressed, an electronic apparatus in which the image quality of image data obtained by capturing an image of a subject is improved can be provided.

### BRIEF DESCRIPTION OF THE DRAWINGS

The invention will be described with reference to the accompanying drawings, wherein like numbers reference like elements.

FIG. 1 is a perspective view illustrating an exemplary configuration of a CIS module.

FIG. 2 is a block diagram illustrating an exemplary configuration of a scanner device using the CIS module.

FIG. 3 is a block diagram illustrating an exemplary configuration of an image sensor chip.

FIG. 4 is a circuit diagram illustrating an equivalent circuit of a pixel unit and a read-out circuit unit corresponding to one pixel.

FIG. 5 is a circuit diagram illustrating a unit block of the pixel unit and the read-out circuit unit.

FIG. 6 is a waveform diagram for illustrating operations of the unit block shown in FIG. 5.

FIG. 7 is a waveform diagram for illustrating an operation for generating control signals for post-stage transfer gates.

FIG. 8 is a plan view illustrating an exemplary layout of the unit block shown in FIG. 5.

FIG. 9 is a cross-sectional view taken along line IX-IX shown in FIG. 8.

FIG. 10 is a cross-sectional view taken along line X-X shown in FIG. 8.

### DESCRIPTION OF EXEMPLARY EMBODIMENTS

Hereinafter, embodiments of the invention will be described in detail with reference to the drawings. The same constituent elements are given the same reference numerals, and a redundant description is omitted.

Electronic Apparatus

Hereinafter, a CIS type scanner device using a contact image sensor (CIS) module including a solid-state image capturing device (image sensor chip) according to one embodiment of the invention will be described as an electronic apparatus according to one embodiment of the invention.

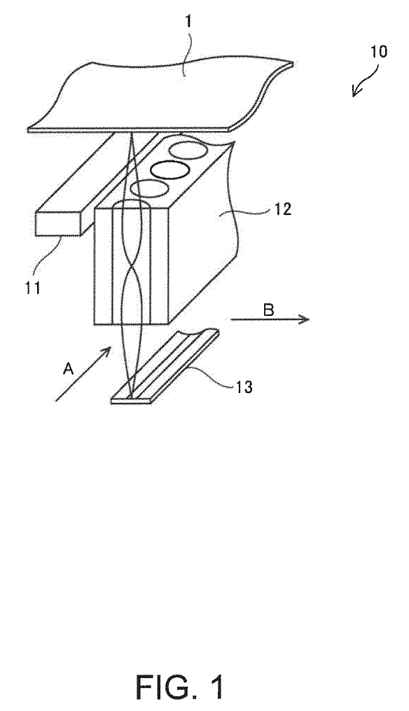

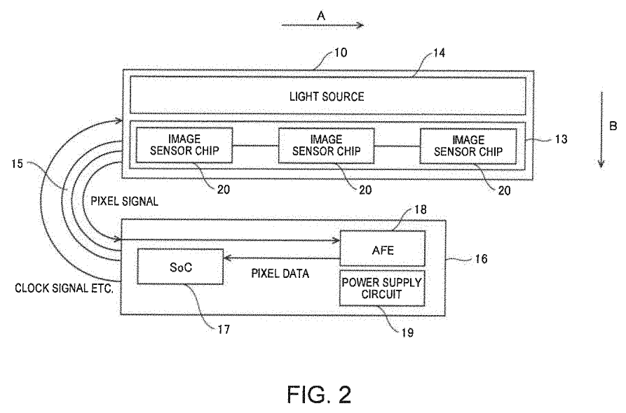

FIG. 1 is a perspective view illustrating an exemplary configuration of a CIS module, and FIG. 2 is a block diagram illustrating an exemplary configuration of a scanner device using the CIS module shown in FIG. 1. As shown in FIG. 1, a CIS module 10 includes a light guide 11 that irradiates a document 1 with light, a lens array 12 that forms an image using light reflected from the document 1, and an image sensor 13 that includes light receiving elements such as photodiodes arranged at a position where the image is formed.

With reference to FIGS. 1 and 2, the CIS module 10 includes a light source 14 that generates light that is to be incident on an end portion of the light guide 11. In the case of a color scanner, the light source 14 includes red (R), green (G), and blue (B) LEDs. The LEDs of three colors are pulse-lighted in a time division manner. The light guide 11 guides light such that a region of the document 1 along the main scanning direction A is irradiated with light generated by the light source 14.

The lens array 12 is constituted by a rod lens array or the like, for example. The image sensor 13 includes a plurality of pixels along the main scanning direction A, and moves in the sub scanning direction B along with the light guide 11 and the lens array 12.

As shown in FIG. 2, the image sensor 13 may be constituted by connecting a plurality of image sensor chips 20 in series, and 12 image sensor chips 20 are connected in series, for example. Each image sensor chip 20 includes 864 pixels, and the 12 image sensor chips include 864×12=10368 pixels in total, for example. Also, each image sensor chip 20 has an elongated rectangular shape having a long side with a length of approximately 18 mm to 20 mm and a short side with a length less than or equal to 0.5 mm, for example.

The CIS module 10, which can move in the sub scanning direction B is connected to a main board 16 that is fixed to the scanner device via a flexible wiring 15. A system on chip (SoC) 17, an analog front end (AFE) 18, and the power supply circuit 19 are mounted on the main board 16.

The system on chip 17 supplies a clock signal, a control signal, and the like to the CIS module 10. A pixel signal generated by the CIS module 10 is supplied to the analog front end 18. The analog front end 18 performs analog/digital conversion on an analog pixel signal, and outputs digital pixel data to the system on chip 17.

The power supply circuit 19 supplies a power supply voltage to the system on chip 17 and the analog front end 18, and supplies a power supply voltage, a reference voltage, and the like to the CIS module 10. Note that portions of the analog front end 18 and the power supply circuit 19, or a light source driver and the like may be mounted on the CIS module 10.

Solid-State Image Capturing Device

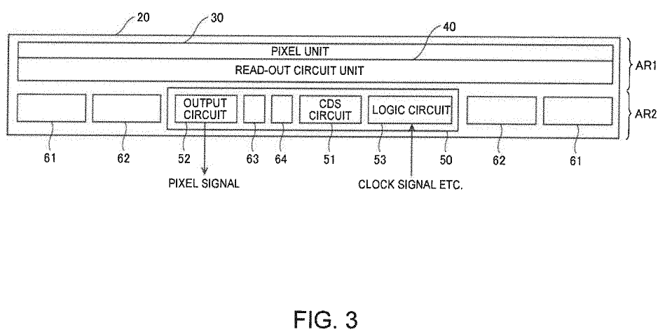

FIG. 3 is a block diagram illustrating an exemplary configuration of an image sensor chip that is a solid-state image capturing device according to one embodiment of the invention. As shown in FIG. 3, the image sensor chip 20 includes a pixel unit 30, a read-out circuit unit 40, and a control circuit unit 50, and may further include capacitors 61 to 64.

In the pixel unit 30, a light receiving element (photodiode, for example) is arranged in each of a plurality of pixels (864 pixels, for example). The read-out circuit unit 40 reads out pixel information by converting a signal charge that is output from the pixel unit 30 to a signal voltage. The control circuit unit 50 performs control so as to generate a pixel signal based on an output voltage of the read-out circuit unit 40. For example, the control circuit unit 50 includes a correlated double sampling (CDS: correlated double sampling) circuit 51, an output circuit 52, and a logic circuit 53.

The correlated double sampling circuit 51 performs correlated double sampling processing on the output voltage of the read-out circuit unit 40. That is, the correlated double sampling circuit 51 samples a voltage immediately after reset and a voltage after exposure, and cancels reset noise by performing processing for obtaining the difference between the sampled voltages, and generates an output voltage according to the intensity of light. The output circuit 52 generates a pixel signal based on the output voltage of the correlated double sampling circuit 51, and outputs the pixel signal. The logic circuit 53 is supplied with a clock signal, a control signal, and the like from the system on chip 17 shown in FIG. 2.

The capacitors 61 are connected between an interconnect of a high potential side power supply potential and an interconnect of a low potential side power supply potential that are arranged in a first region AR1 of the image sensor chip 20, and stabilizes a power supply voltage. Also, the capacitors 62 to 64 are connected between an interconnect of the high potential side power supply potential and an interconnect of the low potential side power supply potential that are arranged in a second region AR2 of the image sensor chip 20, and stabilize the power supply voltage.

Pixel Unit and Read-Out Circuit Unit

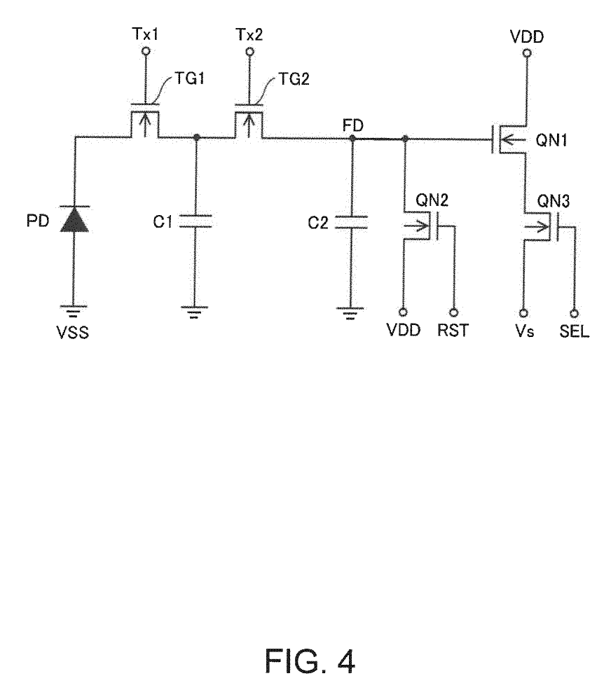

FIG. 4 is a circuit diagram illustrating an equivalent circuit of a pixel unit and a read-out circuit unit corresponding to one pixel. A photodiode PD, for example, is arranged in one pixel of the pixel unit 30 shown in FIG. 3, as a light receiving element having a photoelectric conversion function. The photodiode PD accumulates signal charges according to the intensity of light that is incident thereon.

In order to read out signal charges from the photodiode PD, the read-out circuit unit 40 shown in FIG. 3 includes a pre-stage transfer gate TG1, a charge accumulation capacitor C1, a post-stage transfer gate TG2, a charge accumulation capacitor C2, a buffer transistor QN1, a reset transistor QN2, and a selection transistor QN3. Note that, in the case where an analog shift register is provided at a last stage of the read-out circuit unit 40, the selection transistor QN3 may be included in the analog shift register.

Here, the pre-stage transfer gate TG1 is constituted by an N-channel MOS transistor whose source and drain are a cathode of the photodiode PD and one end of the charge accumulation capacitor C1. Also, the charge accumulation capacitor C1 is constituted by a storage diode,

Furthermore, the post-stage transfer gate TG2 is constituted by an N-channel MOS transistor whose source and drain are one end of the charge accumulation capacitor C1 and one end of the charge accumulation capacitor C2. Also, the charge accumulation capacitor C2 includes an N-type floating diffusion region (floating diffusion) FD arranged in a P-type semiconductor layer.

The photodiode PD, the pre-stage transfer gate TG1, and the post-stage transfer gate TG2 are connected in series between an interconnect of a low potential side power supply potential VSS, and a gate electrode of the buffer transistor QN1. Also, a drain of the buffer transistor QN1 is connected to an interconnect of a high potential side power supply potential VDD. In the following, the power supply potential VSS is assumed to be ground potential 0V.

The reset transistor QN2 has a drain connected to the interconnect of the power supply potential VDD, a source connected to the gate electrode of the buffer transistor QN1, and a gate electrode to which a reset signal RST is supplied. Also, the selection transistor QN3 has a drain connected to a source of the buffer transistor QN1, a source connected to an output terminal of the read-out circuit unit 40, and a gate electrode to which a pixel selection signal SEL is supplied.

When a control signal Tx1 is activated to a high level, the pre-stage transfer gate TG1 transfers signal charges accumulated in the photodiode PD to the charge accumulation capacitor C1 When a control signal Tx2 is activated to a high level, the post-stage transfer gate TG2 transfers signal charges accumulated in the charge accumulation capacitor C1 to the charge accumulation capacitor C2. The charge accumulation capacitor C2 converts the signal charges that have been transferred to a signal voltage.

The reset transistor QN2 resets the gate potential of the buffer transistor QN1 to an initial state potential (power supply potential VDD, for example), when the reset signal RST is activated to a high level. When the reset is released, the buffer transistor QN1 outputs an output voltage according to the signal voltage across the charge accumulation capacitor C2 from the source.

The selection transistor QN3 selects the output voltage of the buffer transistor QN1 when the pixel selection signal SEL is activated to a high level in the order along the main scanning direction A (FIG. 2). Accordingly, the output voltage of the buffer transistor QN1 is output to the output terminal of the read-out circuit unit 40 via the selection transistor QN3, and an output voltage Vs is thereby generated.

Unit Block of Pixel Unit and Read-Out Circuit Unit

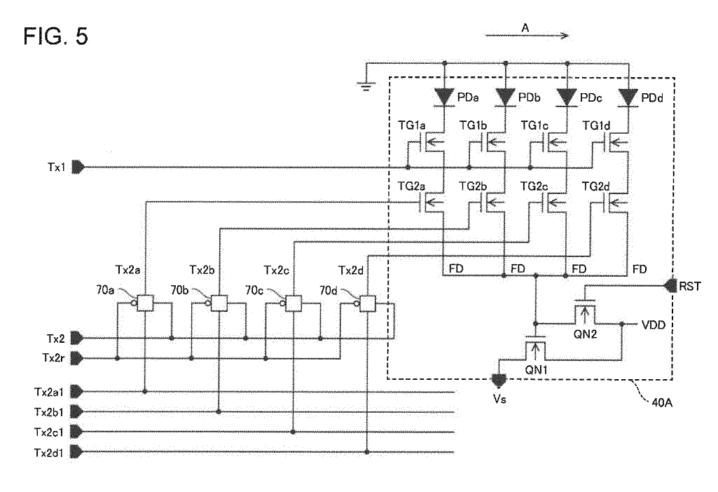

FIG. 5 is a circuit diagram illustrating a unit block of the pixel unit and the read-out circuit unit. As shown in FIG. 5, four photodiodes PDa to PDd that are arranged successively in the main scanning direction A, and the read-out circuit unit for reading out pieces of pixel information by converting signal charges transferred from the photodiodes PDa to PDd to signal voltages constitute one unit block 40A. The number of unit blocks 40A provided in one image sensor chip 20 is 216, for example.

The read-out circuit unit in the unit block 40A includes four pre-stage transfer gates TG1a to TG1d, four post-stage transfer gates TG2a to TG2d, one buffer transistor QN1, and one reset transistor QN2 That is, one buffer transistor QN1 and one reset transistor QN2 are shared between the four photodiodes PDa to PDd.

Here, the four pre-stage transfer gates TG1a to TG1d are turned on at the same time. On the other hand, because the four photodiodes PDa to PDd each constitute one pixel, the four post-stage transfer gates TG2a to TG2d are turned on at different timings. Accordingly, four output voltages Vs1 to Vs4 respectively corresponding to the signal charges of the four photodiodes PDa to PDd are output from the unit block 40A in a time division manner.

A control signal Tx1 that is supplied to the four pre-stage transfer gates TG1a to TG1d in common, and four control signals Tx2a to Tx2d that are respectively supplied to the four post-stage transfer gates TG2a to TG2d are shown in FIG. 5. The common control signal Tx1 is supplied in order to turn on the four pre-stage transfer gates TG1a to TG1d at the same time, as described above.

Here, the control signal Tx1 supplied to the pre-stage transfer gates TG1a to TG1d and the control signals Tx2a to Tx2d respectively supplied to the post-stage transfer gates TG2a to TG2d may have different levels of high level potential. For example, the high level of the control signal Tx1 that is supplied to the pre-stage transfer gates TG1a to TG1d is higher than the power supply potential VDD.

That is, as a result of supplying the control signal Tx1 having higher potential than the power supply potential VDD to the pre-stage transfer gates TG1a to TG1d, the charge transfer capability of the pre-stage transfer gates TG1a to TG1d when turned on is not saturated at an exposure intensity that is less than or equal to a prescribed value, or the saturation level can be improved. Accordingly, the signal charges accumulated in the photodiodes PDa to PDd can be transferred with high transfer capability. Therefore, an image having a high contrast can be formed.

On the other hand, the control signals Tx2a to Tx2d are respectively supplied from the CMOS logic circuits 70a to 70d to the post-stage transfer gates TG2a to TG2d, as shown in FIG. 5. The CMOS logic circuits 70a to 70d generate the control signals Tx2a to Tx2d without a voltage drop, and therefore the transfer capability of the post-stage transfer gates TG2a to TG2d can be improved.

Although an analog switch (transmission gate) constituted by a P-channel MOS transistor and an N-channel MOS transistor is used as each of the CMOS logic circuits 70a to 70d in FIG. 5, the present embodiment is not limited thereto. For example, a circuit that does not cause a voltage drop such as a clocked CMOS logic circuit or an AND gate circuit can be used as each of the CMOS logic circuits 70a to 70d.

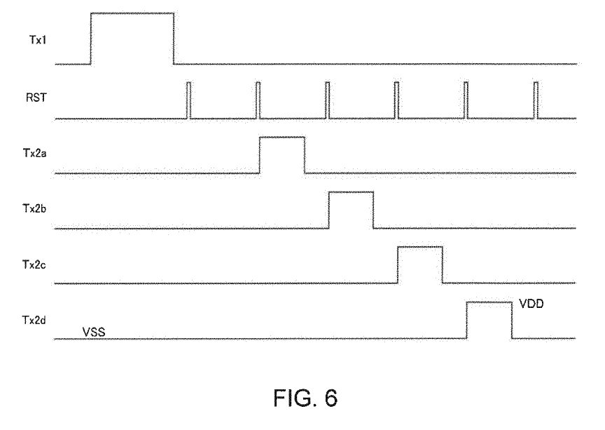

FIG. 6 is a waveform diagram for illustrating operations of the unit block shown in FIG. 5. First, as a result of light being incident on the photodiodes PDa to PDd, the photodiodes PDa to PDd generate signal charges and accumulate the signal charges.

Next, the control signal Tx1 is applied to the pre-stage transfer gates TG1a to TG1d. The pre-stage transfer gates TG1a to TG1d are turned on by the control signal Tx1, and transfer the signal charges accumulated in the photodiodes PDa to PDd to the respective charge accumulation capacitors C1 (FIG. 4).

When the control signal Tx1 is deactivated to a low level, the reset signal RST is activated to a high level. Accordingly, the reset transistor QN2 turns on, and floating diffusion regions FD are reset to an initial state potential (power supply potential VDD, for example).

Thereafter, the four control signals Tx2a to Tx2d are sequentially activated to a high level, as shown in FIG. 6. According to the control signals Tx2a to Tx2d, the four post-stage transfer gates TG2a to TG2d are sequentially turned on, and transfer the charges accumulated in the respective charge accumulation capacitors C1 (FIG. 4) to the respective floating diffusion regions FD.

The voltage of the floating diffusion region FD changes according to the signal charges. The four floating diffusion regions FD are connected to the gate electrode of the buffer transistor QN1 via a common interconnect (hereinafter, referred also as signal interconnect). Therefore, the buffer transistor QN1 is sequentially driven according to the voltages of the four floating diffusion regions FD. Accordingly, the output voltages Vs1 to Vs4 of the four pixels are sequentially output to the output terminal.

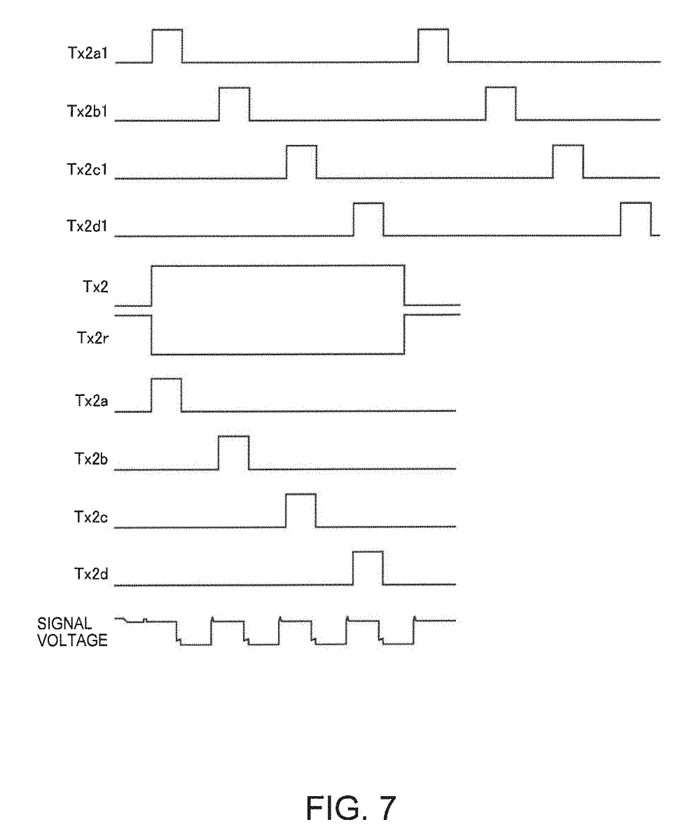

FIG. 7 is a waveform diagram for illustrating an operation for generating the control signals for the post-stage transfer gates. The logic circuit 53 shown in FIG. 3 generates timing signals Tx2a1 to Tx2d1 and supplies the signals to all of the unit blocks. Also, the logic circuit 53 generates block selection signals Tx2 and Tx2r for selecting the unit block 40A shown in FIG. 5.

The CMOS logic circuits 70a to 70d shown in FIG. 5 enter an on-state when the block selection signal Tx2 supplied to a first control terminal is activated to a high level and the block selection signal Tx2r supplied to a second control terminal is deactivated to a low level, and respectively supply the timing signals Tx2a1 to Tx2d1 to the unit block 40A as the control signals Tx2a to Tx2d. Accordingly, transfer periods of the post-stage transfer gates TG2a to TG2d in the unit block 40A are set, signal charges are transferred to the corresponding floating diffusion region FD, and the signal voltages that correspond to the signal charges are generated.

Layout

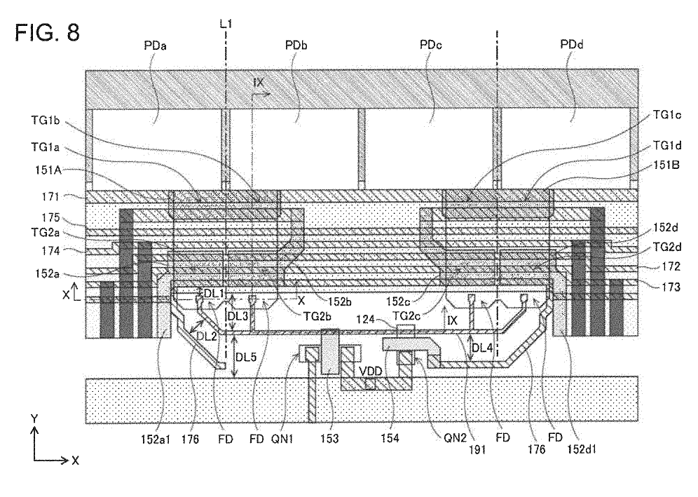

FIG. 8 is a plan view illustrating an exemplary layout of the unit block shown in FIG. 5. Note that, in FIG. 8, portions of gate electrodes and interconnects in a lower layer are shown through interconnects in an upper layer. In the pixel region shown in FIG. 8, the two pre-stage transfer gates TG1a and TG1b shown in FIG. 5 have a common gate electrode 151A that is arranged on the semiconductor layer via a gate insulating film, and the two pre-stage transfer gates TG1c and TG1d have a common gate electrode 151B that is arranged on the semiconductor layer via a gate insulating film. The common gate electrodes 151A and 151B are connected to a control signal interconnect 171, and are supplied with the control signal Tx1.

Also, the four post-stage transfer gates TG2a to TG2d respectively have the four gate electrodes 152a to 152d that are arranged on the semiconductor layer via gate insulating films. The gate electrode 152a is connected to a control signal interconnect 172 via the CMOS logic circuit 70a (FIG. 5), and is supplied with the control signal Tx2a. The gate electrode 152b is connected to a control signal interconnect 173 via the CMOS logic circuit 70b (FIG. 5), and is supplied with the control signal Tx2b.

Similarly, the gate electrode 152c is connected to a control signal interconnect 174 via the CMOS logic circuit 70c (FIG. 5), and is supplied with the control signal Tx2c. The gate electrode 152d is connected to a control signal interconnect 175 via the CMOS logic circuit 70d (FIG. 5), and is supplied with the control signal Tx2d. The control signal interconnects 171 to 175 extend, in a first interconnect layer, along an X-axis direction that is a longitudinal direction of the image sensor chip.

The four floating diffusion regions ED are connected to a gate electrode 153 of the buffer transistor QN1 and a source 124 of the reset transistor QN2 via a signal interconnect 191 that extends along the X-axis direction. Also, the drain of the buffer transistor QN1 and the drain of the reset transistor QN2 are connected to an interconnect of the power supply potential VDD, and a gate electrode 154 of the reset transistor QN2 is connected to a reset signal interconnect 176.

Here, the pre-stage transfer gates TG1a and TG1b are arranged so as to be biased toward an extension line L1 that is an extension of the boundary line between the photodiode PDa and the photodiode PDb. The common gate electrode 151A of the pre-stage transfer gates TG1a and TG1b intersects the extension line L1 in plan view, and the central line thereof in the gate width desirably substantially matches the extension line L1. Note that, in the present application, “in plan view” refers to viewing portions in a direction vertical to the principal surface of the semiconductor layer in a see-through manner.

Also, the post-stage transfer gates TG2a and TG2b are respectively adjacent to the pre-stage transfer gates TG1a and TG1b with a predetermined gap in a Y-axis direction that is orthogonal to the X-axis direction, and are arranged so as to be biased toward the extension line L1. The gate electrodes 152a and 152b of the post-stage transfer gates TG2a and TG2b are desirably arranged such that the central lines of the respective gate electrodes 152a and 152b in the gate width direction are mirror symmetric relative to the extension line L1.

Accordingly, the difference between the length of the charge transfer path from the photodiode PDa to the floating diffusion region FD via the pre-stage transfer gate TG1a and the post-stage transfer gate TG2a and the length of the charge transfer path from the photodiode PDb to the floating diffusion region FD via the pre-stage transfer gate TG1b and the post-stage transfer gate TG2b decreases. Therefore, the variation of the pixel signals caused by the difference in length between the charge transfer paths from the two photodiodes PDa and PDb to the respective floating diffusion regions FD can be suppressed.

Also, because free spaces can be secured on both sides of the common gate electrode 151A and on both sides of the gate electrodes 152a and 152b, the spaces can be used for arranging interconnects in the same layer as the gate electrodes. In FIG. 8, a gate interconnect 152a1 that is connected to the gate electrode 152a is arranged in a space on the left side of the gate electrode 152a.

The features of the layout of the pre-stage transfer gates TG1a and TG1b and the post-stage transfer gates TG2a and TG2b described above can be applied to the layout of the pre-stage transfer gates TG1c and TG1d and the post-stage transfer gates TG2c and TG2d. In FIG. 8, a gate interconnect 152d1 that is connected to the gate electrode 152d is arranged in a space on the right side of the gate electrode 152d.

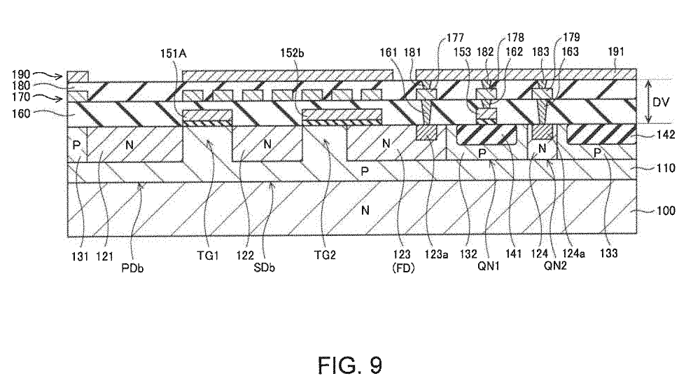

FIG. 9 is a cross-sectional view taken along line IX-IX shown in FIG. 8. As shown in FIG. 9, the solid-state image capturing device includes a P-well 110 formed in an N-type semiconductor substrate 100, and N-type impurity regions 121 to 124 and P-type impurity regions 131 to 133 that are formed in the P-well 110.

The semiconductor substrate 100 is constituted by a silicon (Si) substrate that includes N-type impurities such as antimony (Sb) or phosphorus (P), for example. Also, boron (B) or the like is used as a P-type impurity. Insulating films 141 and 142 made of silicon oxide (SiO₂) or the like are respectively formed in the P-type impurity regions 132 and 133 using a LOCOS method or the like.

The photodiode PDb has an anode constituted by the P-well 110 and a cathode constituted by the N-type impurity region 121. Also, a storage diode SDb has an anode constituted by the P-well 110 and a cathode constituted by the N-type impurity region 122.

In the N-type impurity region 121 or 122, the impurity concentration in the upper portion may be higher than the impurity concentration in the lower portion. Also, a P-type impurity region (pinning layer) with high concentrations may also be provided in an upper portion of the N-type impurity region 121 or 122. As a result of providing a pinning layer, a dark current generated in the N-type impurity region 121 or 122 can be suppressed.

An N-type impurity region 123 corresponds to the floating diffusion region (floating diffusion) FD, and includes a contact region 123a. An N-type impurity region 124 constitutes a source of the reset transistor QN2, and includes a contact region 124a.

Also, on the semiconductor substrate 100 in which the P-well 110 and the like are formed, the common gate electrode 151A of the pre-stage transfer gates TG1a and TG1b, the gate electrode 152b of the post-stage transfer gate TG2b, and the gate electrode 153 of the buffer transistor QN1 are formed via respective gate insulating films. The gate electrodes are made of polysilicon doped with impurities so as to be conductive, or the like, for example.

Here, the charge transfer between the light receiving element such as the photodiode PD and the floating diffusion region FD that are shown in FIG. 4 may be controlled by one transfer gate, and in this case, one of the pre-stage transfer gate TG1 and the post-stage transfer gate TG2 and the charge accumulation capacitor C1 are omitted. In this way, the solid-state image capturing device according to the present embodiment includes a pixel region that includes the light receiving element, the transfer gate (pre-stage transfer gate TG1 or post-stage transfer gate TG2), the floating diffusion region FD that constitutes one end of the charge accumulation capacitor C2, and a buffer transistor QN1.

Furthermore, the solid-state image capturing device according to the present embodiment includes a plurality of interconnect layers that are successively arranged on the semiconductor layer via respective interlayer insulating films. In each of the interconnect layers, a plurality of interconnects that include aluminum (Al), copper (Cu) or the like are arranged, for example. The interlayer insulating films are made of BPSG (Boron Phosphorus Silicon Glass), silicon oxide (SiO₂), or the like.

Reduction of Parasitic Capacitance

In the layout shown in FIGS. 8 and 9, if the parasitic capacitance between the signal interconnect that electrically connects the floating diffusion region FD and the gate electrode 153 of the buffer transistor QN1 and the semiconductor layer or another interconnect such as a power supply interconnect is large, the conversion gain when signal charges are converted into a signal voltage decreases, and the sensitivity of the solid-state image capturing device decreases. Therefore, the solid-state image capturing device according to the present embodiment includes the signal interconnect 191 that is arranged in an N-th interconnect layer that is above the lowest interconnect layer, and that electrically connects the floating diffusion region FD and the buffer transistor QN1. Here, N is an integer of two or more.

As a result of arranging the signal interconnect 191 that electrically connects the floating diffusion region FD and the buffer transistor QN1 in the interconnect layer above the lowest interconnect layer, the distance DV between the signal interconnect 191 and the semiconductor layer increases, and therefore the parasitic capacitance between the signal interconnect 191 and the semiconductor layer is reduced, and the reduction in sensitivity of the solid-state image capturing device due to the reduction in conversion gain when signal charges are converted to a signal voltage can be suppressed. Therefore, the interconnect layer in which the signal interconnect 191 is arranged is desirably the uppermost interconnect layer available.

Here, the solid-state image capturing device may include contact plugs of a first group that are arranged in openings of interlayer insulating films of the first to N-th layers so as to overlap in plan view, and electrically connects the floating diffusion region 123 and the signal interconnect 191, and contact plugs of a second group that are arranged in openings of interlayer insulating films of the first to N-th layers so as to overlap in plan view, and electrically connects the buffer transistor QN1 and the signal interconnect 191.

Accordingly, the electric path between the floating diffusion region 123 and the signal interconnect 191 can be reduced, and the electric path between the buffer transistor QN1 and the signal interconnect 191 can also be reduced. Furthermore, the solid-state image capturing device may include contact plugs of a third group that are arranged in openings of interlayer insulating films of the first to Nth layers so as to overlap in plan view, and electrically connects the source 124 of the reset transistor QN2 and the signal interconnect 191.

The first interlayer insulating film 160, the first interconnect layer 170, the second interlayer nsulating film 180, and the second interconnect layer 190 are shown in FIG. 9, as an example. A plurality of contact plugs 161 to 163 are respectively arranged in openings in the first interlayer insulating film 160, and a plurality of contact plugs 181 to 183 are respectively arranged in openings in the second interlayer insulating film 180. Each contact plug includes tungsten (W), aluminum (Al), copper (Cu), or the like. The first interconnect layer 170 includes relay interconnects 177 to 179.

In the example shown in FIG. 9, the signal interconnect 191 arranged in the second interconnect layer 190 electrically connects the floating diffusion region 123 and the gate electrode 153 of the buffer transistor QN1. That is, the floating diffusion region 123 is electrically connected to the signal interconnect 191 via the contact plugs 161 and 181 of the first group and the relay interconnect 177. Also, the gate electrode 153 of the buffer transistor QN1 is electrically connected to the signal interconnect 191 via the contact plugs 162 and 182 of the second group and the relay interconnect 178. Furthermore, the source 124 of the reset transistor QN2 is electrically connected to the signal interconnect 191 via the contact plugs 163 and 183 of the third group and the relay interconnect 179.

The distance DV between the signal interconnect 191 and the semiconductor layer (P-well 110 in which impurity regions and the like are formed) is approximately 2 μm, for example. Also, the signal interconnect 191 desirably has a width that is smallest in the plurality of interconnects that are arranged in the pixel region. Accordingly, the distance between the signal interconnect 191 and another interconnect in the vicinity thereof increases, and as a result, the parasitic capacitance between the signal interconnect 191 and the other interconnect decreases, and the reduction in sensitivity of the solid-state image capturing device due to the reduction in conversion gain when signal charges are converted to a signal voltage can be suppressed.

That is, with respect to the widths of interconnects in a semiconductor device including the solid-state image capturing device, some widths are defined according to the design rules of the semiconductor device. A minimum width that can be processed among those widths is used as the width of the signal interconnect 191. Alternatively, the parasitic capacitance between the signal interconnect 191 and another interconnect in the vicinity thereof may be reduced by reducing the thickness of the signal interconnect 191 and reducing the facing area between interconnects.

Also, the signal interconnect 191 desirably does not intersect with another interconnect in plan view. Accordingly, the increase in parasitic capacitance between the signal interconnect 191 and another interconnect due to the interconnect 191 intersecting with the other interconnect can be prevented from occurring. Furthermore, the distance DL between the signal interconnect 191 and another interconnect in a direction parallel to a principal surface (upper surface in the diagram) of the semiconductor layer is desirably larger than the distance DV between the signal interconnect 191 and the semiconductor layer in a direction vertical to the principal surface of the semiconductor layer. Accordingly, the parasitic capacitance between the signal interconnect 191 and another interconnect can be sufficiently smaller than the parasitic capacitance between the signal interconnect 191 and the semiconductor layer.

In the example shown in FIGS. 8 and 9, distances DL1 to DL4 between the signal interconnect 191 and the reset signal interconnect 176 in the direction parallel to the principal surface of the semiconductor layer are larger than the distance DV between the signal interconnect 191 and the semiconductor layer in the direction vertical to the principal surface of the semiconductor layer. Also, the distance DL5 between the signal interconnect 191 and the interconnect of the power supply potential VDD in the direction parallel to the principal surface of the semiconductor layer is larger than the distance DV between the signal interconnect 191 and the semiconductor layer in the direction vertical to the principal surface of the semiconductor layer.

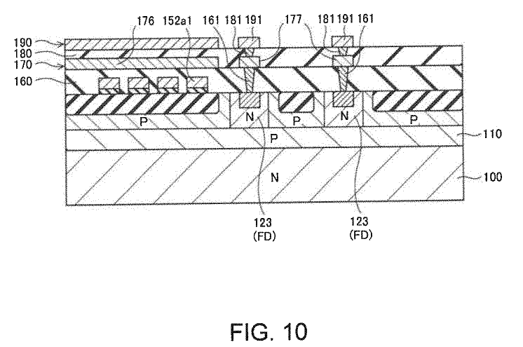

FIG. 10 is a cross-sectional view taken along line X-X shown in FIG. 8. The signal interconnect 191 electrically connected to the floating diffusion region 123, the reset signal interconnect 176, and the gate interconnect 152a1 connected to the gate electrode 152a of the post-stage transfer gate TG2a shown in FIG. 8 are shown in FIG. 10.

The signal interconnect 191 is arranged in the second interconnect layer 190, and the reset signal interconnect 176 is arranged in the first interconnect layer 170, and therefore the actual distance between the signal interconnect 191 and the reset signal interconnect 176 is larger than the distance between the signal interconnect 191 and the reset signal interconnect 176 in the direction parallel to the principal surface of the semiconductor layer,

Relaxation of Capacitive Coupling

In the case where the gate interconnect 152a1 connected to the gate electrode 152a of the post-stage transfer gate TG2a is arranged in the vicinity of the signal interconnect 191 as shown in FIG. 8, if the capacitive coupling between the signal interconnect 191 and the gate interconnect 152a1 is strong, the change in the potential of the gate interconnect 152a1 adversely affects the potential of the signal interconnect 191.

That is, when the potential of the gate interconnect 152a1 is at a high level, signal charges are transferred to the floating diffusion region FD via the post-stage transfer gate TG2a, the signal charges are converted to a signal voltage, and the signal voltage is supplied to the signal interconnect 191. Therefore, if the capacitive coupling between the signal interconnect 191 and the gate interconnect 152a1 is strong, when the potential of the gate interconnect 152a1 transitions to a high level, the potential of the signal interconnect 191 may change.

Similarly, in the case where the gate interconnect 152d1 connected to the gate electrode 152d of the post-stage transfer gate TG2d is arranged in the vicinity of the signal interconnect 191, if the capacitive coupling between the signal interconnect 191 and the gate interconnect 152d1 is strong, the change in the potential of the gate interconnect 152d1 adversely affects the potential of the signal interconnect 191.

Therefore, the solid-state image capturing device according to the present embodiment further includes a guard interconnect that is arranged between the signal interconnect 191 and a gate interconnect connected to a transfer gate in plan view. In the example shown in FIGS. 8 and 10, the reset signal interconnect 176 that is arranged between the signal interconnect 191 and the gate interconnects 152a1 and 152d1 in plan view is used as the guard interconnect.

In this case, the capacitive coupling between the signal interconnect 191 and the gate interconnects 152a1 and 152d1 can be reduced by the reset signal interconnect 176 serving as the guard interconnect, and as a result, the adverse effect in that the change in the potential of the gate interconnect 152a1 or 152d1 adversely affects the potential of the signal interconnect 191 can be suppressed. In a period in which the buffer transistor QN1 outputs a signal component, the potential of the reset signal interconnect 176 is fixed at a low level (power supply potential VSS), and therefore a shielding effect can be obtained.

Also, according to the present embodiment, as a result of using the solid-state image capturing device in which the parasitic capacitance between the signal interconnect 191 that electrically connects the floating diffusion region 123 and the buffer transistor QN1 and the semiconductor layer or another interconnect is reduced, and the reduction in sensitivity due to the reduction in conversion gain when signal charges are converted to a signal voltage is suppressed, an electronic apparatus in which image quality of image data obtained by capturing a subject is improved can be provided.

Furthermore, the present invention can be applied, other than the scanner device, to electronic apparatuses that capture a subject and generate image data, such as a drive recorder, a digital movie camera, a digital still camera, a mobile terminal such as a mobile phone, a TV phone, a surveillance television monitor, a measurement apparatus, and a medical apparatus, for example.

In the embodiments described above, a case where the N-type impurity region and the like are formed in the P-type semiconductor layer was described, but the invention is not limited to the embodiments described above. For example, the invention can also be applied to a case where a P-type impurity region and the like are formed in an N-type semiconductor layer. In this way, many modifications can be made within the technical idea of the invention by a person having ordinary skill in the art.

This application claims priority from Japanese Patent Application No.2016-178287 filed in the Japanese Patent Office on Sep. 13, 2016, the entire disclosure of which is hereby incorporated by reference in its entirely.

What is claimed is:

1. A solid-state image capturing device comprising:
a pixel region including a light receiving element, a transfer gate, a floating diffusion region, and a buffer transistor; and
an interconnect that is arranged in an N-th interconnect layer (N is an integer of two or more), and electrically connects the floating diffusion region and the buffer transistor.

2. The solid-state image capturing device according to claim 1, further comprising:
contact plugs of a first group that are arranged in openings of interlayer insulating films of first to N-th layers so as to overlap in plan view, and electrically connect the floating diffusion region and the interconnect; and
contact plugs of a second group that are arranged in openings of the interlayer insulating films of the first to N-th layers so as to overlap in plan view, and electrically connect the buffer transistor and the interconnect.

3. The solid-state image capturing device according to claim 1, wherein the interconnect has a width that is smallest in a plurality of interconnects that are arranged in the pixel region.

4. The solid-state image capturing device according to claim 1, wherein the interconnect does not intersect with another interconnect in plan view.

5. The solid-state image capturing device according to claim 1, wherein a distance between the interconnect and another interconnect in a direction parallel to a principal surface of a semiconductor layer in which the pixel region is provided is larger than a distance between the interconnect and the semiconductor layer n a direction vertical to the principal surface of the semiconductor layer.

6. The solid-state image capturing device according to claim 1, further comprising a guard interconnect that is arranged between the interconnect and an interconnect connected to the transfer gate in plan view.

7. An electronic apparatus comprising the solid-state image capturing device according to claim 1.
